(19) United States
(12) Patent Application Publication
(10) Pub. No.: US 2008/0206445 A1
(43) Pub. Date: Aug. 28, 2008

(54) Selective separation processes

(76) Inventors: John Peck, West Seneca, NY (US); Michael Mark Litwin, Cheektowaga, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/709,435

(22) Filed: Feb. 22, 2007

(51) Int. Cl. C23C 16/00

(52) U.S. Cl. 427/58; 118/726; 203/99; 427/255.26

(57) ABSTRACT

This invention relates to a separation process comprising (i) introducing a vapor phase mixture into a condensing apparatus, said vapor phase mixture comprising at least one desirable component and at least one undesirable component; (ii) controlling the temperature in the condensing apparatus utilizing a heat-transfer gas; and (iii) operating the condensing apparatus at a temperature and a pressure sufficient to selectively condense at least a portion of said vapor phase mixture and thereby yield a recovered content containing said at least one desirable component. The separation process is useful in semiconductor applications such as recovery of unreacted organometallic compound precursors in chemical vapor deposition or atomic layer deposition processes.

### FIELD OF THE INVENTION

This invention relates to a separation process comprising (i) introducing a vapor phase mixture into a condensing apparatus, said vapor phase mixture comprising at least one desirable component and at least one undesirable component; (ii) controlling the temperature in the condensing apparatus utilizing a heat-transfer gas; and (iii) operating the condensing apparatus at a temperature and pressure sufficient to selectively condense at least a portion of said vapor phase mixture and thereby yield a recovered content containing said at least one desirable component.

### BACKGROUND OF THE INVENTION

Chemical vapor deposition methods are employed to form films of material on substrates such as wafers or other surfaces during the manufacture or processing of semiconductors. In chemical vapor deposition, a chemical vapor deposition precursor, also known as a chemical vapor deposition chemical compound, is decomposed thermally, chemically, photochemically or by plasma activation, to form a thin film having a desired composition. For instance, a vapor phase chemical vapor deposition precursor can be contacted with a substrate that is heated to a temperature higher than the decomposition temperature of the precursor, to form a metal-containing film on the substrate. Preferably, chemical vapor deposition precursors are volatile, heat decomposable and capable of producing uniform films under chemical vapor deposition conditions.

The cost for the production of a thin film by chemical vapor deposition depends on the cost of the organometallic compound and on the ratio of the amount of organometallic compound consumed in the deposition reactor to the amount of the organometallic compound vaporized in the precursor delivery system, that is, on precursor utilization. Precursor utilization in conventional chemical vapor deposition may be as low as 10% or less, and most of the introduced source gas containing organometallic compound may actually be treated as an exhaust gas. In conventional processes, the organometallic compound in the exhaust gas may be discarded even if the organometallic compound is in an unreacted state. The production cost of a deposition film in such a case where the precursor utilization is low is further affected by the cost of the organometallic compound.

Organometallic compounds are generally expensive as they require a multiplicity of steps for synthesis. For example, even when the metal itself is not so expensive, the cost significantly increases when the metal is synthetically converted into an organometallic compound. The production cost of a film by conventional chemical vapor deposition inevitably increases due to the price of the expensive organometallic compound.

A thin film of a precious metal such as ruthenium is expected to be heavily used in the future as a material for a thin film electrode to yield a high-performance electrode. A precious metal is naturally a rare metal and is expensive, and its organometallic compound is significantly expensive. Accordingly, when a precious metal film is produced by conventional chemical vapor deposition, the cost for forming a film can be expected to further increase.

Organometallic compound precursors are used in the production of thin films. Future film-forming processes may justify organometallic compound recovery, on the basis of high compound cost and low process efficiency. In applications where compound recovery is justifiable, it would be beneficial to be able to condense certain components (e.g., original compound molecule) of the exhaust gas, while preventing other components (e.g., coreactants and byproducts) from condensing. A problem with conventional recovery processes is the inability to selectively separate multi-component mixtures from the exhaust of various thin film deposition systems.

Accordingly, there is a need in the art for developing new methods to selectively recover from exhaust gases unreacted organometallic compounds used in chemical vapor deposition, and thereby reduce the production cost of a film, especially for chemical vapor deposition of thin films using a precious metal such as ruthenium.

### SUMMARY OF THE INVENTION

This invention relates in general to a method for employing a variable temperature condenser to selectively separate and recover components of a process gas. The condenser is operated at a temperature of from about 20° C. (293 K) to about −196° C. (77 K), preferably from about 20° C. (293 K) to about −100° C. (173 K), and more preferably from about −30° C. (243 K) to about −100° C. (173 K), and at a pressure of from about 10,000 Torr to about 1×10⁻⁶ Torr, preferably from about 1,000 Torr to about 1×10⁻³ Torr, and more preferably from about 10 Torr to about 0.01 Torr, to safely and efficiently separate and recover one or more components in the effluent leaving a chamber, e.g., a deposition chamber. The condensing is accomplished by means of a heat transfer gas such as cold nitrogen, argon, helium, hydrogen, carbon dioxide or clean dry air. The condenser temperature is controlled by adjusting the flow and/or temperature of the heat transfer gas.

This invention relates in part to a separation process comprising (i) introducing a vapor phase mixture into a condensing apparatus, said vapor phase mixture comprising at least one desirable component and at least one undesirable component; (ii) controlling the temperature in the condensing apparatus utilizing a heat-transfer gas; and (iii) operating the condensing apparatus at a temperature and pressure sufficient to selectively condense at least a portion of said vapor phase mixture and thereby yield a recovered content containing said at least one desirable component.

This invention also relates in part to a method for recovering an organometallic compound comprising (i) heating and vaporizing said organometallic compound in a dispensing apparatus to yield a source gas; (ii) introducing said source gas into a reactor containing a substrate and allowing the source gas to react on a surface of the substrate to yield a metal-containing thin film, e.g., a metal or metal compound such as an oxide, nitride, carbide, and the like; (iii) removing an effluent gas from the reactor, said effluent gas comprising unreacted source gas; (iv) introducing the effluent gas into a condensing apparatus; (v) controlling the temperature in the condensing apparatus utilizing a heat-transfer gas; and (vi) operating the condensing apparatus at a temperature and pressure sufficient to selectively condense at least a portion of said unreacted source gas and thereby yield a recovered content containing unreacted organometallic compound.

This invention further relates in part to an apparatus for forming a thin film comprising (i) a dispensing apparatus for heating and vaporizing an organometallic compound to yield a source gas; (ii) a reactor containing a substrate for reacting the source gas on a surface of the substrate to yield a metal-containing thin film, e.g., a metal or metal compound such as an oxide, nitride, carbide, and the like; and (iii) a variable temperature condensing apparatus for selectively condensing at least a portion of an effluent gas from the reactor, said effluent gas comprising unreacted source gas.

### BRIEF DESCRIPTION OF THE DRAWINGS

FIG. 1 depicts an illustrative process flow and corresponding mass balance associated with this invention. This mass balance accounts for the flow and composition of the process gas at different stages throughout a thin film deposition system.

FIG. 2 is a schematic of a variable temperature condenser apparatus used in Example 2 below.

FIG. 3 graphically depicts the history of the condenser temperature and the nitrogen flow in Example 2 below.

FIG. 4 graphically depicts vapor pressure data for ammonia and 1-ethyl-1′-methylruthenocene in Example 1 below.

### DETAILED DESCRIPTION OF THE INVENTION

As indicated above, the invention employs a variable temperature condenser. The variable temperature condenser has the ability to control the rate of heat removal, and resulting temperature of the condenser. The variable temperature condenser utilizes a heat-transfer gas which is first cooled by a low-temperature heat-sink (e.g., liquid nitrogen) and then directed at the condenser. The rate of heat removal from the condenser and its corresponding temperature are primarily controlled by the temperature of the heat-sink and flow of heat-transfer gas. The variable temperature condenser can be used to separate a gas mixture. By controlling the temperature of the condenser, desired components of the mixture can be condensed, while undesired components will not condense.

To effect selective separation of desired components from undesired components in a gas mixture, the variable temperature condenser is operated at a temperature of from about ambient or 20° C. (293 K) to about −196° C. (77 K), preferably from about ambient or 20° C. (293 K) to about −100° C. (173 K), and more preferably from about −30° C. (243 K) to about −100° C. (173 K). The variable temperature condenser is also operated at a pressure of from about 10,000 Torr to about 1×10⁻⁶ Torr, preferably from about 1,000 Torr to about 1×10⁻³ Torr, and more preferably from about 10 Torr to about 0.01 Torr.

The ability to selectively condense components from a process gas has important implications, including purification and safety. Controlling the temperature of the condenser can be used to increase the concentration of a desired component in the condensed phase. Preventing undesired components from condensing also increases the capacity of a batch condenser. In addition, certain components (e.g., ammonia and oxygen) may develop high pressure in a condenser, if it returns to room temperature (e.g., idle state, replacement upon reaching capacity, unintentional loss of heat removal). The low pressure (about 1 Torr) of thin film deposition processes generally requires a low condenser temperature (−100° C. to −30° C.), in order to efficiently (greater than 99%) condense organometallic precursors. Unfortunately, using a fixed temperature condenser may result in the condensation of unwanted components. This may result in accidental worker exposure, in the event that the equipment pressure limit is exceeded, upon absence of heat removal.

Using a gas as the heat transfer medium is a cleaner and safer alternative to using a liquid, such as a closed loop glycol/water circulator. Residual fluid in the cold finger is undesirable for recovery of air sensitive precursors, which require unloading in an inert atmosphere, e.g., glove box.

Precursor recovery is an emerging technology. Prior practice and inventions have discussed the use of cold traps operated at fixed temperature (e.g., chilled bath and liquid nitrogen). A variable temperature condenser can reach the desired temperature quicker than a chilled bath, due to the lower heat capacity of a gas, compared to a liquid. Using nitrogen as the heat transfer gas has the added benefit of preventing frost buildup and possible plugging of the cold finger inlet tube.

This invention offers flexibility in terms of the use of different precursors and coreactants. For example, using a fixed temperature condenser operating at a temperature of −196° C. (e.g., liquid nitrogen), in some circumstances precursors cannot safely be separated from a mixture containing ammonia or oxygen. On the other hand, if a chilled water trap (e.g., ice bath) is used, the temperature may not be low enough to condense the desired component (i.e., precursor). The thermal gradient (non-uniformity) across the cold finger is less when using a variable temperature condenser, due to the added convective heat transfer, compared to chilled bath or liquid nitrogen bath.

The advantage of this invention is increased flexibility of the precursor recovery equipment, compared to prior art (fixed temperature condenser). The increased flexibility allows a single design to accommodate separation of multiple types of mixtures.

As a general example, consider precursor A is a component of a process gas, and is combined with a carrier gas B and coreactant C to form the process gas. In addition, at least one byproduct (D) is generated as a result of the film forming process. The mixture (A, B, C, and D) exits the film forming reactor and is passed through a condenser. To determine which, if any, of the components will condense, we need to know the (I) flow rate of each component, (2) pressure in the condenser, (3) temperature of the condenser and (4) the vapor pressure curves for each component.

In an embodiment, this invention is a deposition process for forming a thin film which includes a step of selectively recovering an organometallic compound component from an exhaust gas which has been conventionally discarded, and optionally a purifying step of purifying the recovered organometallic compound to thereby eliminate a by-product formed in a film forming step by deposition. According to this process, the organometallic compound is recycled. As a recovering technique, this invention employs a technique in which the exhaust gas is cooled and is recovered as a recovered content. An optional purifying technique is distilling the recovered content. These deposition thin film processes selectively recover the organometallic compound by utilizing a variable temperature condenser as described herein.

An embodiment of this invention involves placing the variable temperature condenser downstream of the thin film deposition system. As the exhaust gas mixture flows through the variable temperature condenser, the temperature of the interior surface of the variable temperature condenser will dictate which of the components are condensed and which pass through. In the absence of experimental data, vapor pressure data can be used to determine the optimum temperature which maximizes both retention of the desired component and separation selectivity (% of desired component condensed/% of undesired component condensed). The ultimate goal of condensing the unused precursor from the exhaust gas mixture is to reuse it as a raw material for thin film deposition. Prior to reusing the precursor, it desirably should be purified to remove contaminants introduced by the process. Subsequent purification costs can be minimized using the variable temperature condenser as the first step in the purification process.

Purifying the recovered organometallic compound is optional. In the purifying step, a reaction byproduct may be separated and eliminated from the recovered organometallic compound component, since a reaction byproduct (a decomposition product) formed through a reaction of a source gas is introduced into the exhaust gas in a film-forming step by deposition.

An embodiment of this invention involves a deposition process for forming a thin film, which includes a vaporizing step of heating and vaporizing an organometallic compound to yield a source gas; a thin film forming step of introducing the source gas onto a substrate and allowing the source gas to react on a surface of the substrate to yield a metal-containing thin film, e.g., a metal or metal compound such as an oxide, nitride, carbide, and the like; and a recovering step of cooling an exhaust gas containing a reaction product formed in the thin film forming step and an unreacted source gas to condense or solidify the unreacted source gas to thereby yield a recovered content containing a liquid or solid organometallic compound. The process optionally involves a purifying step of separating and purifying the organometallic compound from the recovered content.

Because an organometallic compound generally exhibits a low melting and boiling point, phase change can occur at relatively low temperatures. In accordance with this invention, an exhaust gas is cooled to introduce phase change of the organometallic compound from a gaseous state into a solid state or liquid state to thereby recover the organometallic compound. The recovered organometallic compound is optionally further purified to yield a high purity organometallic compound. This invention can recover a component containing an unreacted organometallic compound and can extract the organometallic compound in a state which can be recycled. This invention therefore can reduce production cost of a thin film through recycled organometallic compound, even when the utilization efficiency of the material is low.

In an embodiment, this invention relates to a method for recovering an organometallic compound comprising: (i) providing a vapor phase reagent dispensing apparatus; (ii) adding a reagent which is a liquid or solid at ambient temperature to said vapor phase reagent dispensing apparatus, said reagent comprising an organometallic compound; (iii) heating the reagent in said vapor phase reagent dispensing apparatus to a temperature sufficient to vaporize the reagent to provide vapor phase reagent; (iv) feeding a carrier gas into said vapor phase reagent dispensing apparatus; (v) withdrawing the vapor phase reagent and carrier gas from said vapor phase reagent dispensing apparatus through said vapor phase reagent discharge line; (vi) feeding the vapor phase reagent and carrier gas into a deposition chamber; (vii) contacting the vapor phase reagent with a substrate on a heatable susceptor within the deposition chamber; (viii) discharging any remaining effluent through an effluent discharge line connected to the deposition chamber; (ix) feeding the effluent into a condensing apparatus, said effluent comprising unreacted vapor phase reagent; (x) controlling the temperature in the condensing apparatus utilizing a heat-transfer gas; and (xi) operating the condensing apparatus at a temperature and pressure sufficient to selectively condense at least a portion of said unreacted vapor phase reagent and thereby yield a recovered content containing unreacted organometallic compound.

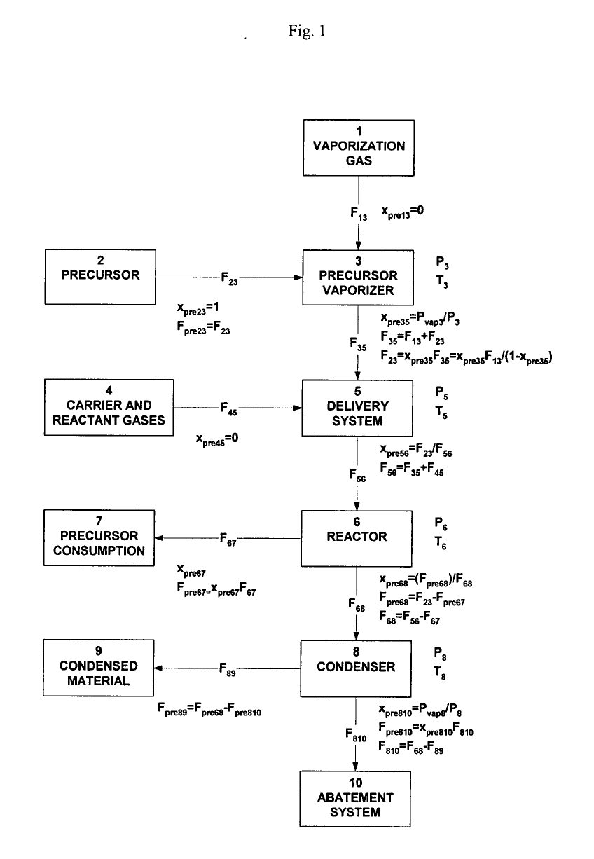

FIG. 1 describes an illustrative process flow and corresponding mass balance associated with this invention. This mass balance accounts for the flow and composition of the process gas at different stages throughout a thin film deposition system. The overall flow(s) to and from each node is designated by subscripts (e.g., the overall flow from node 1 to 2 is designated “F₁₂”). The flow of precursor is designated by an addition of “pre” to the subscript (e.g., the flow of precursor from node 2 to 3 is designated “Fₚᵣₑ₂₃”).

A vaporization gas (e.g., nitrogen, argon and helium) is used to convey the precursor vapors from the precursor vaporizer (node 3) to the delivery system (node 5). The mol fraction of precursor in the gas mixture exiting the vaporizer is designated as xₚᵣₑ₃₅. If we assume that the mixture exiting the vaporizer is saturated with precursor, then the theoretical value of xₚᵣₑ₃₅ is equal to the precursor vapor pressure divided by the total pressure. In practice, the mixture may not be completely saturated and the degree of saturation (0 to 100%) can vary depending on the equipment and process conditions. The degree of saturation can be measured and correlated as a function of process conditions. For the sake of simplicity, we will assume that the degree of saturation is 100%.

Additional gas species, including coreactants (e.g., hydrogen, oxygen), are added to the process gas mixture in the delivery system. From the delivery system, the process gas is then sent to the reactor. A substrate within the reactor is contacted with the process gas at the desired conditions (e.g., temperature and pressure) to deposit a thin film, with the appropriate properties (e.g., thickness, composition and morphology). The two primary routes for precursor consumption in the reactor, designated as Fₚᵣₑ₆₇, are the film deposited on the intended substrate and unwanted film deposits on the interior surfaces of the reactor. Although it is again undesirable, precursor may also be consumed by gas phase reactions.

The amount of precursor consumed (Fₚᵣₑ₆₇) in the reactor divided by the amount of precursor vaporized (Fₚᵣₑ₂₃) is defined as the precursor utilization (also referred to as deposition efficiency). For many thin film processes, precursor utilization is less than 100%. For processes where precursor utilization is very low (e.g., less than 10%), low precursor utilization may prohibit the use of precursors which are the preferred solution, based on technical performance. Condensing and recycling unused precursor may enable the use of higher value precursors, which generate optimum film properties.

Liquid organometallic compound precursors such as described above also can be atomized and sprayed onto a substrate. Atomization and spraying means, such as nozzles, nebulizers and others, that can be employed are known in the art.

In preferred embodiments of the invention, an organometallic compound, such as described above, is employed in gas phase deposition techniques for forming powders, films or coatings. The compound can be employed as a single source precursor or can be used together with one or more other precursors, for instance, with vapor generated by heating at least one other organometallic compound or metal complex. More than one organometallic compound precursor, such as described above, also can be employed in a given process.

Deposition can be conducted in the presence of other gas phase components. In an embodiment of the invention, film deposition is conducted in the presence of at least one non-reactive carrier gas. Examples of non-reactive gases include inert gases, e.g., nitrogen, argon, helium, as well as other gases that do not react with the organometallic compound precursor under process conditions. In other embodiments, film deposition is conducted in the presence of at least one reactive gas. Some of the reactive gases that can be employed include but are not limited to hydrazine, oxygen, hydrogen, air, oxygen-enriched air, ozone (O₃), nitrous oxide (N₂O), water vapor, organic vapors, ammonia and others. As known in the art, the presence of an oxidizing gas, such as, for example, air, oxygen, oxygen-enriched air, O₃, N₂O or a vapor of an oxidizing organic compound, favors the formation of a metal oxide film.

In an embodiment, hydrogen or another reducing gas may be used in a BEOL (back end of line) atomic layer deposition process at temperatures below 300° C. so that the deposition can be carried out in a manner compatible with the rest of the BEOL integration strategy. An illustrative atomic layer deposition strategy for forming BEOL interconnects using ruthenium is as follows: low K repair, tantalum nitride atomic layer deposition, ruthenium atomic layer deposition and copper electrochemical deposition. Hydrogen reducible ruthenium complexes may also be used for the integration of ruthenium in MIM stacked cell DRAM capacitors.

Deposition methods described herein can be conducted to form a film, powder or coating that includes a single metal or a film, powder or coating that includes a single metal or metal compound such as an oxide, nitride, carbide, and the like. Mixed films, powders or coatings also can be deposited, for instance mixed metal oxide films. A mixed metal oxide film can be formed, for example, by employing several organometallic precursors, at least one of which being selected from the organometallic compounds described above.

Vapor phase film deposition can be conducted to form film layers of a desired thickness, for example, in the range of from about 1 nm to over 1 mm. The precursors described herein are particularly useful for producing thin films, e.g., films having a thickness in the range of from about 10 nm to about 100 nm. Films of this invention, for instance, can be considered for fabricating metal electrodes, in particular as p-type metal electrodes in CMOS (complementary metal oxide semiconductor) logic, as capacitor electrodes for DRAM applications, and as dielectric materials.

The method also is suited for preparing layered films, wherein at least two of the layers differ in phase or composition. Examples of layered film include metal-insulator-semiconductor, and metal-insulator-metal.

In an embodiment, the invention is directed to a method that includes the step of decomposing vapor of an organometallic compound precursor described above, thermally, chemically, photochemically or by plasma activation, thereby forming a film on a substrate. For instance, vapor generated by the compound is contacted with a substrate having a temperature sufficient to cause the organometallic compound to decompose and form a film on the substrate.

The organometallic compound precursors can be employed in chemical vapor deposition or, more specifically, in metalorganic chemical vapor deposition processes known in the art. For instance, the organometallic compound precursors described above can be used in atmospheric, as well as in low pressure, chemical vapor deposition processes. The compounds can be employed in hot wall chemical vapor deposition, a method in which the entire reaction chamber is heated, as well as in cold or warm wall type chemical vapor deposition, a technique in which only the substrate is being heated.

The organometallic compound precursors described above also can be used in plasma or photo-assisted chemical vapor deposition processes, in which the energy from a plasma or electromagnetic energy, respectively, is used to activate the chemical vapor deposition precursor. The compounds also can be employed in ion-beam, electron-beam assisted chemical vapor deposition processes in which, respectively, an ion beam or electron beam is directed to the substrate to supply energy for decomposing a chemical vapor deposition precursor. Laser-assisted chemical vapor deposition processes, in which laser light is directed to the substrate to affect photolytic reactions of the chemical vapor deposition precursor, also can be used.

The method of the invention can be conducted in various chemical vapor deposition reactors, such as, for instance, hot or cold-wall reactors, plasma-assisted, beam-assisted or laser-assisted reactors, as known in the art.

Examples of substrates that can be coated employing the method of the invention include solid substrates such as metal substrates, e.g., Al, Ni, Ti, Co, Pt, Ta; metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); barrier materials, e.g., TiN, TaN; or on substrates that include combinations of materials. In addition, films or coatings can be formed on glass, ceramics, plastics, thermoset polymeric materials, and on other coatings or film layers. In preferred embodiments, film deposition is on a substrate used in the manufacture or processing of electronic components. In other embodiments, a substrate is employed to support a low resistivity conductor deposit that is stable in the presence of an oxidizer at high temperature or an optically transmitting film.

The method of this invention can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the method of the invention also can be integrated with other steps in wafer manufacturing or processing, e.g., masking, etching and others.

Chemical vapor deposition films can be deposited to a desired thickness. For example, films formed can be less than 1 micron thick, preferably less than 500 nanometers and more preferably less than 200 nanometers thick. Films that are less than 50 nanometers thick, for instance, films that have a thickness between about 0.1 and about 20 nanometers, also can be produced.

Organometallic compound precursors described above also can be employed in the method of the invention to form films by atomic layer deposition (ALD) or atomic layer nucleation (ALN) techniques, during which a substrate is exposed to alternate pulses of precursor, reactive gas (e.g., oxidizer) and inert gas streams. Sequential layer deposition techniques are described, for example, in U.S. Pat. No. 6,287,965 and in U.S. Pat. No. 6,342,277. The disclosures of both patents are incorporated herein by reference in their entirety.

For example, in one ALD cycle, a substrate is exposed, in step-wise manner, to: a) an inert gas; b) inert gas carrying precursor vapor; c) inert gas; and d) oxidizer, alone or together with inert gas. In general, each step can be as short as the equipment will permit (e.g., milliseconds) and as long as the process requires (e.g., several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

The precursor is decomposed to form a metal-containing film on the substrate. The reaction also generates organic material from the precursor. The organic material is solubilized by the solvent fluid and easily removed away from the substrate. Metal oxide films also can be formed, for example by using an oxidizing gas.

In an example, the deposition process is conducted in a reaction chamber that houses one or more substrates. The substrates are heated to the desired temperature by heating the entire chamber, for instance, by means of a furnace. Vapor of the organometallic compound can be produced, for example, by applying a vacuum to the chamber. For low boiling compounds, the chamber can be hot enough to cause vaporization of the compound. As the vapor contacts the heated substrate surface, it decomposes and forms a metal-containing film, e.g., a metal or metal compound such as an oxide, nitride, carbide, and the like. As described above, an organometallic compound precursor can be used alone or in combination with one or more components, such as, for example, other organometallic precursors, inert carrier gases or reactive gases.

In a system that can be used in producing films by the method of the invention, raw materials can be directed to a gas-blending manifold to produce process gas that is supplied to a deposition reactor, where film growth is conducted. Raw materials include, but are not limited to, carrier gases, reactive gases, purge gases, precursor, etch/clean gases, and others. Precise control of the process gas composition is accomplished using mass-flow controllers, valves, pressure transducers, and other means, as known in the art. An exhaust manifold can convey gas exiting the deposition reactor, as well as a bypass stream, to a vacuum pump. An abatement system, downstream of the vacuum pump, can be used to remove any hazardous materials from the exhaust gas. The deposition system can be equipped with in-situ analysis system, including a residual gas analyzer, which permits measurement of the process gas composition. A control and data acquisition system can monitor the various process parameters (e.g., temperature, pressure, flow rate, etc.).

The organometallic compound precursors described above can be employed to produce films that include a single metal or a film that includes a single metal oxide, nitride, carbide or the like. Mixed films also can be deposited, for instance mixed metal-containing films. Such films are produced, for example, by employing several organometallic precursors. Metal films also can be formed, for example, by using no carrier gas, vapor or other sources of oxygen.

Films formed by the methods described herein can be characterized by techniques known in the art, for instance, by X-ray diffraction, Auger spectroscopy, X-ray photoelectron emission spectroscopy, atomic force microscopy, scanning electron microscopy, and other techniques known in the art. Resistivity and thermal stability of the films also can be measured, by methods known in the art.

Referring to FIG. 1 again, precursor not consumed in film forming exit the reactor exhaust. The composition of the process gas exhausted from the reactor is calculated based on the precursor utilization. A condenser downstream of the reactor can be used to remove components from the vapor phase. The temperature of the condenser will affect the composition of the condensed phase. For precursor recovery, the goal is to maximize the condensation of the precursor and minimize the condensation of other species. If the precursor reaches a saturated state in the vapor phase of the condenser, the theoretical mol fraction of the precursor exiting the condenser (xₚᵣₑ₈₁₀) can be calculated by dividing the precursor vapor pressure by the total pressure. Similar to prior discussion pertaining to the precursor vaporizer, in practice the degree of saturation in the condenser is not 100%. The condenser temperature should be controlled in order to retain the maximum amount of precursor and optimize the selectivity of precursor condensation, versus condensation of other species. The condenser efficiency is defined as the amount of precursor condensed in the condenser divided by the amount of precursor introduced to the condenser.

Conditions for cooling the exhaust gas in the recovering step are determined by the properties of the organometallic compound used. A specific mechanism for cooling the exhaust gas and recovering the organometallic compound in the recovering step includes, for example, a configuration in which a variable temperature condenser is mounted on piping from the reactor chamber.

When the condenser approaches its capacity, the condensed materials must be removed. The precursor is then separated from the condensed material and returned to the precursor reservoir to be used in the film forming process. Any uncondensed precursor proceeds to the abatement system, where it is disposed of in the appropriate manner.

The recovered content recovered in the recovering step may basically be composed of an unreacted organometallic compound and a reaction product. Such reaction products may include water, carbon dioxide, aldehydes, formic acid, oxides or hydroxides of the compound, and other low molecular weight compounds. A metal atom is eliminated from the organometallic compound by a reaction for the formation of a thin film, and the organometallic compound is decomposed to thereby yield these low molecular weight compounds. Such water and other reaction products are impurities but can be easily separated and eliminated in a purification step, as they have physical properties greatly different from those of the target organometallic compound to be purified.

Accordingly, it is preferred to separate the organometallic compound by distillation of the recovered content in the purification step. An organometallic compound having a good purity can be directly separated by distillation, since the organometallic compound generally has a low melting and boiling point and can induce phase change at relatively low temperatures, as described above. Additionally, distillation does not require complex equipment and is a relatively easy purification technique.

Organometallic compounds for use in this invention are not particularly limited. Organic compounds of a variety of metals such as ruthenium, platinum, palladium, copper, indium, lanthanum, tantalum, tungsten, molybdenum, lanthanides, zirconium, niobium, aluminum, titanium, and rhenium may be used as materials for the formation of a thin film. Some of these metals are inexpensive as metal itself, but organometallic compounds thereof are significantly expensive. The cost in the formation of a thin film of these metals or metal oxides, nitrides, carbides and the like can therefore be reduced.

Additionally, this invention is particularly useful in the production of a thin film using an organometallic compound of a precious metal such as platinum, palladium, ruthenium, rhodium, iridium, or osmium, in consideration of recently increased demands for a thin film of a precious metal and in consideration of high prices of organic compounds of such precious metals.

Finally, a chemical vapor deposition apparatus for producing a thin film, to which variable temperature condenser apparatus is applied, will be illustrated. The chemical vapor deposition process for forming a thin film is performed with a variable temperature condenser apparatus and optionally a purifying step added to a conventional chemical vapor deposition apparatus for producing a thin film, without major change of its configuration. Specifically, the chemical vapor deposition apparatus for producing a thin film according to this invention is a chemical vapor deposition apparatus for producing a thin film, which includes a solution containing an organometallic compound as a material, a heating device for heating the solution to vaporize the organometallic compound to thereby yield a source gas, and a reactor for allowing the source gas to react to thereby form a metal-containing thin film, e.g., a metal or metal compound such as an oxide, nitride, carbide, and the like, on a substrate. The apparatus includes, on the downstream side from the reactor, a variable temperature condenser for obtaining a recovered content containing the organometallic compound from an exhaust gas composed of a reaction product formed through a reaction and an unreacted source gas, and optionally a purifying device for separating and purifying the organometallic compound from the recovered content.

Other embodiments of this invention involving the equipment include the following: for processes operated at sub-atmospheric pressure (thin film deposition is typically conducted at atmospheric pressure or below), the condenser should be designed appropriately (e.g., vacuum compatible); the condenser should have metal seals to minimize the possibility of permeation of, and subsequent reaction with, atmospheric components (e.g., water and oxygen); the condenser should be designed and operated so the condensation efficiency is high (this can be accomplished through a number of techniques, including maximizing surface area and residence time); the temperature of the condenser is monitored using a sensor (e.g., thermocouple); and the temperature signal is used to adjust the flow of the heat transfer gas (e.g., nitrogen) in order to control the rate of heat removal.

Those skilled in the art will recognize that numerous changes may be made to the method described in detail herein, without departing in scope or spirit from this invention as more particularly defined in the claims below. For example, this invention could be applied outside of thin film deposition (e.g., for general separation technology in the chemical or pharmaceutical industries or for analytical purposes); multiple variable temperature condenser units can be used to separate a mixture of multiple compounds; the condenser can be equipped with a valve to periodically drain liquids; multiple sensors can be used to determine condenser temperature profile; a heater can be installed on the heat-transfer fluid line in order to heat the trap; the use of metal gasket seals on the condenser; a sensor (thermocouple) may be installed in a liquid nitrogen dewar to indicate when it should be refilled; a sensor may be installed in the condenser to indicate when it has reached capacity; and the like. A flow alarm signal, indicating unacceptable (e.g., none) flow of heat transfer gas, can be used to alert the operator or automatically trigger an event.

For organometallic compounds recovered by the method of this invention, optional purification can occur through recrystallization, more preferably through extraction of reaction residue (e.g., hexane) and chromatography, and most preferably through sublimation and distillation.

Examples of techniques that can be employed to characterize the recovered organometallic compounds include, but are not limited to, analytical gas chromatography, nuclear magnetic resonance, thermogravimetric analysis, inductively coupled plasma mass spectrometry, differential scanning calorimetry, vapor pressure and viscosity measurements.

Relative vapor pressures, or relative volatility, of organometallic compound precursors described above can be measured by thermogravimetric analysis techniques known in the art. Equilibrium vapor pressures also can be measured, for example by evacuating all gases from a sealed vessel, after which vapors of the compounds are introduced to the vessel and the pressure is measured as known in the art.

Also, within the scope of this invention, the temperature of the heat transfer gas can be reduced using methods other than liquid nitrogen. Alternative heat sink mediums include, for example, liquids and solids maintained at temperatures below −50° C., such as cryogenic liquids (e.g., argon and helium) and solid carbon dioxide.

In another embodiment, this invention relates to the use of multiple variable temperature condensers in series. Using multiple variable temperature condensers in series provides the ability to selectively condense multiple components. Depending on the particular application, the recovered content from each of the variable temperature condensers arranged in series may be considered reusable material or waste material.

In a further embodiment of this invention, the recovered content may be directly conveyed (e.g., pumped) back to the input of the process (e.g., recycled).

In addition to other applications described herein, the variable temperature condensers can be used for synthesis and analytical purposes.

As used herein, condensing refers to changing from a gaseous or vapor state to a liquid or solid state. Condensing may also include changing from a liquid state to a solid state.

Various modifications and variations of this invention will be obvious to a worker skilled in the art and it is to be understood that such modifications and variations are to be included within the purview of this application and the spirit and scope of the claims.

### EXAMPLE 1

1-Ethyl-1′-methylruthenocene and ammonia are used for the deposition of ruthenium films by plasma enhanced atomic layer deposition (PEALD) process. In this process, the substrate is exposed using a 4 step cycle. The process gas composition during each of the steps is described in the table below.

| Step | Process gas composition |
|---|---|
| 1 | 1-ethyl-1′-methylruthenocene/argon |
| 2 | Argon purge |
| 3 | Ammonia/argon plasma |
| 4 | Argon purge |

A general range of conditions, for the PEALD process using 1-ethyl-1′-methylruthenocene and ammonia, is described in the table below.

| | |
|---|---|
| Duration of each step, seconds | 0.1 to 10000 |
| Reactor Pressure, Torr | 0.001 to 1000 |
| Substrate Temperature, ° C. | 25 to 600 |
| Total process gas flow, standard cubic | 1 to 10000 |
| centimeters per minute | |
| Mole fraction of 1-ethyl-1′- | 0 to 1 |
| methylruthenocene in exhaust gas | |
| Mole fraction of ammonia in exhaust gas | 0 to 1 |

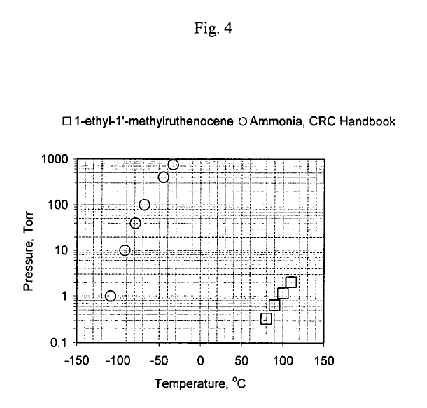

Vapor pressure data for ammonia and 1-ethyl-1′-methylruthenocene are shown in FIG. 4.

The vapor pressure of these two materials can be approximated by the equation:

Pᵥₐₚ(Torr)=e^{[A-B/T(K)]}

Based on the data in FIG. 4, the best fit of the constants A and B in the above equation, as well as the R-squared values, are:

| | A | B | R² |
|---|---|---|---|
| Ammonia | 21.11 | −3421 | 0.9932 |
| 1-ethyl-1′-methylruthenocene | 22.07 | −8176 | 0.9998 |

In order to calculate what fraction of a particular component in the exhaust gas will condense, we need to know the temperature and pressure of the condenser. We also need to know the composition of the exhaust gas, e.g., the mole fraction of each component, entering the condenser.

The goal is to condense 100% of the 1-ethyl-1′-methylruthenocene and 0% (none) of the ammonia. The most efficient separation will occur when the condenser temperature is above the dew point of ammonia, in order to prevent ammonia from condensing. The dew point temperature is the temperature at which a liquid or solid is in equilibrium with the vapor phase (e.g., rate of evaporation/sublimation is equal to rate of condensation). The process is also constrained by the desire to keep the condenser temperature low enough to condense as much 1-ethyl-1′-methylruthenocene as possible. For a mixture containing 1-ethyl-1′-methylruthenocene and ammonia, the optimum condenser temperature is slightly above the dew point of ammonia.

To illustrate the utility of a variable temperature condenser, consider the following example. The total pressure inside the condenser is 1 Torr. In a pulsed process (e.g., ALD or PEALD), the mole fraction of the components in the exhaust gas mixture (e.g., ammonia and 1-ethyl-1′-methylruthenocene) entering the condenser will vary with time. The maximum partial pressure of either ammonia or 1-ethyl-1′-methylruthenocene is 1 Torr. At a partial pressure of 1 Torr, the dew point temperature of 1-ethyl-1′-methylruthenocene is approximately 100° C. If there is no mass transfer resistance, we can calculate the temperature required to reduce the partial pressure of 1-ethyl-1′-methylruthenocene to a desired value. For example, to reduce the partial pressure of 1-ethyl-1′-methylruthenocene by 99.999% (e.g., from 1 Torr to 0.00001 Torr) would require a condenser temperature of −30° C. Due to the presence of mass transfer limitations in real-world applications, operating at the lowest possible condenser temperature is preferred. The dew point temperature of ammonia at a pressure of 1 Torr is −116° C. As a result, we would want to operate the condenser at a temperature slightly above −116° C., in order to prevent ammonia from condensing, yet condense as much 1-ethyl-1′-methylruthenocene as possible.

Changing process conditions will affect the optimum condenser temperature. Specifically, increasing the partial pressure of ammonia (e.g., by increasing the total pressure, at a fixed composition) requires an increase in the condenser temperature to prevent condensation of ammonia. In addition, the use of coreactants other than ammonia and/or the presence of reaction byproducts will also affect the minimum allowable condenser temperature. A variable temperature condenser can easily adapt to these types of process changes, in contrast to fixed temperature equipment (e.g., liquid nitrogen).

By using a dry inert gas (e.g., nitrogen) as the heat transfer medium, two benefits are yielded. First, the thermal mass of the system is decreased, relative to liquid heat transfer fluids. This decreases the time it takes to change the temperature of the condenser (e.g., cooling the condenser to process temperature or bringing the condenser back up to room temperature). The second benefit pertains to manipulating the condenser in a glove box, which may be necessary in order to remove the condensed precursor (assuming the precursor is air-sensitive). Using a dry inert gas (e.g., nitrogen) as the heat transfer fluid prevents the condenser from being exposed to water and/or other heat transfer liquids, which are undesirable for subsequent use in a glove-box.

### EXAMPLE 2

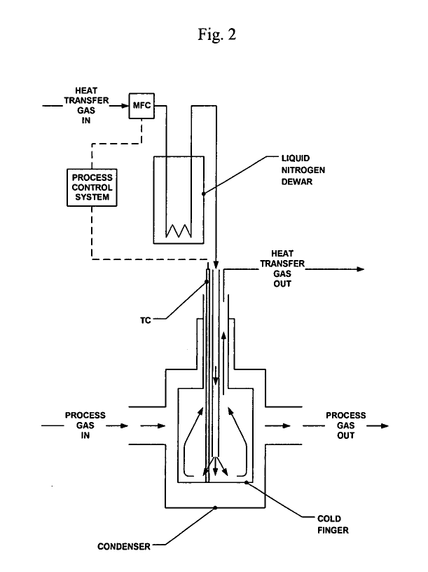

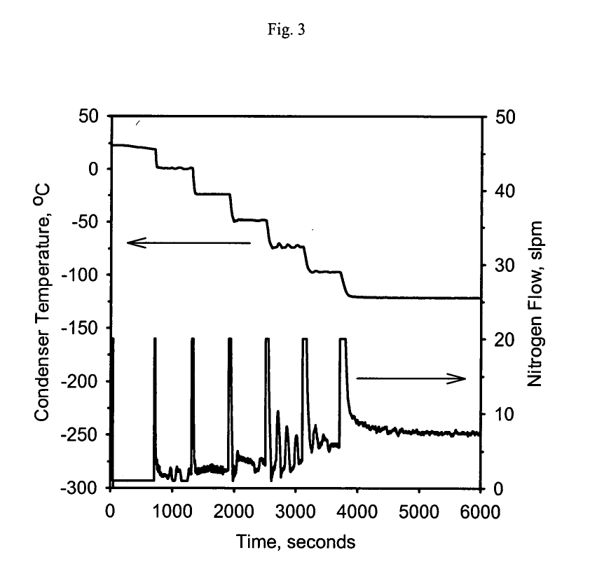

A 20 standard liter per minute (slpm) mass flow controller, supplied by MKS Instruments, was used to control the flow of nitrogen to a coil submerged in a dewar (2 liter capacity) filled with liquid nitrogen. The nitrogen heat transfer gas was subsequently directed at the cold finger of the process gas condenser (commercially available from MDC Vacuum Products, KDFT4150-2LN, 4 inch body diameter, 1.5 inch inlet and outlet tube diameter). The nitrogen heat transfer gas was conveyed using ¼ inch stainless steel tubing with a wall thickness of 0.035 inches. The flow of nitrogen heat transfer gas to the cold finger was modulated using the condenser temperature as the feedback signal. A type K thermocouple (⅛ inch diameter, 12 inch long stainless steel sheath) was used to monitor the cold finger temperature. FIG. 2 depicts the apparatus used. FIG. 3 shows the history of the condenser temperature and nitrogen flow. Temperatures below −100° C. (173 K) were achievable, and this example demonstrates that condenser temperature can be automatically controlled using a feedback configuration. The setpoint temperature was decreased from 25° C. to −125° C. in steps of 25° C., every 10 minutes. At maximum flow (20 standard liters per minute), the temperature of the condenser could be decreased by approximately 30° C./minute.

### EXAMPLE 3

The ability to operate and control a condenser at temperatures below −100° C. (173 K) was evaluated in an apparatus as depicted in FIG. 2. Using nitrogen as the heat transfer gas, a flow of about 10 standard liters per minute was supplied through a coil submerged in a dewar of liquid nitrogen. The heat transfer gas was then vented onto the cold finger of a stainless steel liquid nitrogen trap (condenser), resulting in a cold finger temperature below −100° C. (173 K). The temperature of the cold finger could also be controlled at values between −100° C. (173 K) and ambient temperature using the signal from the condenser thermocouple in a feedback loop, to adjust the flow of nitrogen through the coil and the resulting heat removal rate.

1. A separation process comprising (i) introducing a vapor phase mixture into a condensing apparatus, said vapor phase mixture comprising at least one desirable component and at least one undesirable component; (ii) controlling the temperature in the condensing apparatus utilizing a heat-transfer gas; and (iii) operating the condensing apparatus at a temperature and pressure sufficient to selectively condense at least a portion of said vapor phase mixture and thereby yield a recovered content containing said at least one desirable component.

2. The separation process of claim 1 wherein said at least one desirable component comprises an organometallic compound.

3. The separation process of claim 2 wherein said organometallic compound comprises a ruthenium-containing compound, a platinum-containing compound, a hafnium-containing compound, a tantalum-containing compound, a molybdenum-containing compound, a tungsten-containing compound, a titanium-containing compound, a lanthanum-containing compound, a palladium-containing compound, an aluminum-containing compound, a copper-containing compound, a zirconium-containing compound, a niobium-containing compound, an iridium-containing compound, a cadmium-containing compound, a bismuth-containing compound, a strontium-containing compound, a silicon-containing compound, or a lanthanide-containing compound.

4. The separation process of claim 1 wherein said heat-transfer gas comprises nitrogen, argon, helium, hydrogen, carbon dioxide or clean dry air.

5. The separation process of claim 1 wherein said condensing apparatus is operated at a temperature of from about 20° C. (293 K) to about −196° C. (77 K).

6. The separation process of claim 1 wherein said condensing apparatus is operated at a pressure of from about 10,000 Torr to about 1×10⁻⁶ Torr.

7. The separation process of claim 1 wherein the condensing apparatus temperature is controlled by adjusting the flow and/or temperature of heat transfer gas.

8. The separation process of claim 1 further comprising purifying the at least one desired component from said recovered content.

9. A method for recovering an organometallic compound comprising (i) heating and vaporizing said organometallic compound in a dispensing apparatus to yield a source gas; (ii) introducing said source gas into a reactor containing a substrate and allowing the source gas to react on a surface of the substrate to yield a metal-containing thin film; (iii) removing an effluent gas from the reactor, said effluent gas comprising unreacted source gas; (iv) introducing the effluent gas into a condensing apparatus; (v) controlling the temperature in the condensing apparatus utilizing a heat-transfer gas; and (vi) operating the condensing apparatus at a temperature and pressure sufficient to selectively condense at least a portion of said unreacted source gas and thereby yield a recovered content containing unreacted organometallic compound.

10. The method of claim 9 wherein said organometallic compound comprises a ruthenium-containing compound, a platinum-containing compound, a hafnium-containing compound, a tantalum-containing compound, a molybdenum-containing compound, a tungsten-containing compound, a titanium-containing compound, a lanthanum-containing compound, a palladium-containing compound, an aluminum-containing compound, a copper-containing compound, a zirconium-containing compound, a niobium-containing compound, an iridium-containing compound, a cadmium-containing compound, a bismuth-containing compound, a strontium-containing compound, a silicon-containing compound, or a lanthanide-containing compound.

11. The method of claim 9 wherein said heat-transfer gas comprises nitrogen, argon, helium, hydrogen, carbon dioxide or clean dry air.

12. The method of claim 9 wherein said condensing apparatus is operated at a temperature of from about 20° C. (293 K) to about −196° C. (77 K).

13. The method of claim 9 wherein said condensing apparatus is operated at a pressure of from about 10,000 Torr to about 1×10⁻⁶ Torr.

14. The method of claim 9 wherein the condensing apparatus temperature is controlled by adjusting the flow and/or temperature of heat transfer gas.

15. The method of claim 9 further comprising purifying the organometallic compound from said recovered content.

16. The method of claim 9 wherein said substrate is comprised of a material selected from the group consisting of a metal, a metal silicide, a semiconductor, an insulator and a barrier material.

17. The method of claim 9 wherein said substrate is a patterned wafer.

18. The method of claim 9 in which the reactor is a deposition chamber selected from a chemical vapor deposition chamber or an atomic layer deposition chamber.

19. An apparatus for forming a thin film comprising (i) a dispensing apparatus for heating and vaporizing an organometallic compound to yield a source gas; (ii) a reactor containing a substrate for reacting the source gas on a surface of the substrate to yield a metal-containing thin film; and (iii) a variable temperature condensing apparatus for selectively condensing at least a portion of an effluent gas from the reactor, said effluent gas comprising unreacted source gas.

20. The apparatus of claim 19 in which the reactor is a deposition chamber selected from a chemical vapor deposition chamber or an atomic layer deposition chamber.

21. A separation process comprising (i) introducing a vapor phase mixture into a condensing apparatus, said vapor phase mixture comprising at least one desirable component comprising an organometallic compound and at least one undesirable component; (ii) controlling the temperature in the condensing apparatus by adjusting flow and/or temperature of a heat transfer gas; (iii) operating the condensing apparatus at a temperature of from about 20° C. (293 K) to about −196° C. (77 K) and pressure of from about 10,000 Torr to about 1×10⁻⁶ Torr to selectively condense at least a portion of said vapor phase mixture and thereby yield a recovered content containing said at least one desirable component, and (iv) purifying the at least one desirable component from said recovered content.

22. A separation process comprising (i) introducing a vapor phase mixture into a first condensing apparatus, said vapor phase mixture comprising at least one desirable component comprising an organometallic compound and at least one undesirable component; (ii) controlling the temperature in the first condensing apparatus by adjusting flow and/or temperature of a heat transfer gas; (iii) operating the first condensing apparatus at a temperature of from about 20° C. (293 K) to about −196° C. (77 K) and pressure of from about 10,000 Torr to about 1×10⁻⁶ Torr to selectively condense at least a portion of said vapor phase mixture and thereby yield a recovered content containing said at least one desirable component, (iv) repeating steps (i) through (iii) for at least one other condensing apparatus configured in series with said first condensing apparatus, and (v) purifying the at least one desirable component from said recovered content for each condensing apparatus.

23. The separation process of claim 22 wherein said recovered content containing at least one desirable component from said first condensing apparatus is different from said recovered content containing at least one desirable component from said at least one other condensing apparatus.
